(19) United States
(12) Patent Application Publication
(10) Pub. No.: US 2022/0262986 A1
(43) Pub. Date: Aug. 18, 2022

(54) SEMICONDUCTOR DEVICE AND FABRICATING METHOD THEREFOR

(71) Applicant: COMPOUNDTEK PTE. LTD., SINGAPORE (SG)

(72) Inventor: GUNASAGAR S., SINGAPORE (SG)

(73) Assignee: COMPOUNDTEK PTE. LTD., SINGAPORE (SG)

(21) Appl. No.: 17/628,885

(22) PCT Filed: Aug. 9, 2021
(86) PCT No.: PCT/SG2021/050464

§ 371 Date: Jan. 20, 2022

(30) Foreign Application Priority Data
Aug. 11, 2020 (SG) 10202007625Q

(51) Int. Cl. H01L 33/44; H01L 33/00; H01L 33/62

(52) U.S. Cl. CPC H01L 33/44; H01L 33/005; H01L 2933/0025; H01L 2933/0066; H01L 33/62

(57) ABSTRACT

The present invention relates to a semiconductor device (10), comprising a substrate (11), a semiconductor layer (12), a stressor layer (13), an insulator barrier (14) and a plurality of electrical connectors. The semiconductor layer (12) is sandwiched between the substrate (11) and the stressor layer (13). The stressor layer (13) is on top of the semiconductor layer (12) and is capable of inducing strain on the semiconductor layer (12). A method for fabricating a semiconductor device comprises the steps of forming a substrate (110), epitaxially growing a semiconductor layer on the substrate (120), depositing a stressor layer on the semiconductor layer (130) and forming a plurality of electrical connectors (140), wherein the electrical connectors are capable of electrically connecting the semiconductor device to an external circuit.

### FIELD OF THE INVENTION

The disclosures made herein relate generally to semiconductors and more particularly to a semiconductor device such as semiconductor laser, light emitting diode, laser diode, electronic diode, photodiode, sensor and neutron detector, with a stressor layer and a method for fabricating the semiconductor device.

### BACKGROUND OF THE INVENTION

Monolithically integrated photonic circuits are mainly used as optical data links in applications including high performance computing (HPC), inter-device interconnects and optical memory extension (OME). They are also very much useful as input/output means in mobile devices to enable data exchange between the mobile devices and a host device and/or cloud servers at a rapid rate which is not possible with wireless technology or electrical cables.

In semiconductors, band gap defines characteristics e.g. carrier mobility, photon absorption, emission wavelength, etc., of the corresponding semiconductor and therefore their applications e.g. radiation sensing, light emitting, etc. For example, germanium photodiodes are an integral part of silicon photonics platforms, due to the ability of germanium to absorb near infrared radiation between 850 nm and 1550 nm. Wavelengths between 1.3 and 1.6 microns are especially important for optical communications as both silica of optical fibers and silicon of photonics integrated circuits are transparent at these wavelengths, while germanium is strongly absorbing. Direct bandgap of germanium can be reduced from a bulk value of 0.80 eV by subjecting it to tensile strain, which in turn enhances absorption at longer wavelengths into the L-band.

FIG. 4 shows a graphical representation of responsivity of a germanium (Ge) film of thickness 1.65 microns when subjected to 0.20%, 0.58% and 0.76% strain. It can be seen that the responsivity of the Ge film is improved to a broader wavelength when subjected to high strain levels.

U.S. Pat. No. 9,490,318 B2 discloses a three dimensional strained semiconductor e.g. such as semiconductor lasers, light emitting diodes, laser diodes, electronic diodes, photodiodes, sensors, detectors (e.g. neutron detectors), wherein an array of three dimensional semiconductor pillars are formed above a substrate by etching the substrate, such that cavity regions are formed between two adjacent pillars. A thin film of silicon dioxide, silicon nitride, silicon oxynitride or boron is deposited on a surface of the cavity regions and the pillars to induce strain on the pillars. An amount of strain induced on the pillars can be varied by modifying an amount of intrinsic stress in the thin film which is controllable by modifying one or more deposition conditions e.g. deposition time, temperature, pressure, hydrogen content in the thin film, etc.

Even though control over the induced strain is possible from the teachings of '318, it needs extreme care in configuring the deposition conditions to induce a target strain as any deviations in the conditions may result in damaging the pillars. Furthermore, it is a tedious process to deposit a thin film of uniform thickness over a three dimensional structure, as the film tends to form a thicker coating at a bottom portion of each pillar as compared to a corresponding top portion. Alternatively, the strain may be increased by increasing thickness of the stressor film. However, the stressor film tend to crack when the thickness of the stressor film is greater than 200 nanometers.

Hence, there is a need for a method of fabricating a semiconductor device with a stressor layer, wherein a higher level of strain can be induced without a need for configuring fabrication conditions or material composition for different strain levels. Furthermore, there is a need for a semiconductor device that can be fabricated with desired radiation absorption or emission characteristics in a simple manner, while minimizing damages during fabrication.

### SUMMARY OF THE INVENTION

The present invention relates to a semiconductor device and a method for fabricating the semiconductor device. The device comprises a substrate, a semiconductor layer, a stressor layer and plurality of connectors for connecting the device to an external circuit. The semiconductor layer is sandwiched between the stressor layer and the substrate, wherein the stressor layer induces strain on the semiconductor layer.

The device comprises an insulator barrier provided on the substrate for defining a cavity, wherein the barrier forms a perimeter of the cavity while the substrate forms a bottom of the cavity, such that the semiconductor layer and the stressor layer are confined to the cavity. Preferably, the stressor layer is formed by a chemical vapor deposition (CVD) such as plasma enhanced CVD (PECVD) and low pressure CVD (LPCVD), of a complementary metal oxide semiconductor (CMOS) process-compatible dielectric such as silicon nitride. Preferably, the semiconductor device is a photodiode. Alternatively, the semiconductor device may be a light emitting diode, laser diode, photovoltaic cell, sensor or neutron detector.

In one aspect of the present invention, the semiconductor layer is capable of absorbing electromagnetic radiation such as near infrared radiation.

In another aspect of the present invention, the semiconductor layer is capable of emitting electromagnetic radiation such as visible light radiation.

The method for fabricating a stressor layer for the semiconductor device, comprises the steps of forming a substrate, epitaxially growing a semiconductor layer on the substrate and depositing a stressor layer on the semiconductor layer, wherein the stressor layer is capable of inducing strain on the semiconductor layer.

In another aspect, the stressor layer is deposited by means of chemical vapor deposition (CVD) such as plasma enhanced CVD (PECVD) or low pressure CVD (LPCVD). Before epitaxially growing the semiconductor layer, an insulator barrier is formed on the substrate to define a cavity, wherein the barrier forms a perimeter around the cavity while the substrate forms a bottom of the cavity, such that the semiconductor layer and the stressor layer are confined to the cavity. Furthermore, an excess stressor layer is removed, such that a combined thickness of the semiconductor layer and the stressor layer does not exceed a depth of the cavity. Preferably, the excess stressor layer is removed by a chemical mechanical polishing (CMP) process. Alternatively, the excess stressor layer may also be removed by a chemical etching process.

Confinement of the stressor layer to the cavity prevents cracking of the stressor layer which is often seen when the thickness of the stressor layer exceeds a few hundred nanometers, particularly when the thickness exceeds 200 nanometers. Thus, thickness of the stressor layer can be increased beyond 200 nanometers without cracking by increasing depth of the cavity, which in turn increases the strain induced on the semiconductor layer. Furthermore, the increased strain enhances absorption or emission capability of the semiconductor layer. By this way, the present invention allows achieving desired radiation absorption or emission characteristics without a need for changing conditions of fabricating the semiconductor device, and thus the semiconductor device with desired characteristics can be fabricated in a simple and inexpensive manner, while minimizing damages during fabrication.

### BRIEF DESCRIPTION OF THE ACCOMPANYING DRAWINGS

The present invention will be fully understood from the detailed description given herein below and the accompanying drawings which are given by way of illustration only, and thus are not limitative of the present invention, wherein:

In the appended drawings:

FIG. 1 shows a cross sectional view of the semiconductor device, in accordance with an exemplary embodiment of the present invention;

FIGS. 2A-2E show cross sectional view of the semiconductor device during fabrication process, in accordance with an exemplary embodiment of the present invention; and

FIG. 3 shows a flow diagram of the method for fabricating a stressor layer for the semiconductor device, in accordance with an exemplary embodiment of the present invention; and

FIG. 4 shows a graphical representation of photocurrent responsivity of a germanium photodiode subjected to different strain levels.

### DETAILED DESCRIPTION OF THE INVENTION

Detailed description of preferred embodiments of the present invention is disclosed herein. It should be understood, however, that the embodiments are merely exemplary of the present invention, which may be embodied in various forms. Therefore, the details disclosed herein are not to be interpreted as limiting, but merely as the basis for the claims and for teaching one skilled in the art of the invention. The numerical data or ranges used in the specification are not to be construed as limiting. The following detailed description of the preferred embodiments will now be described in accordance with the attached drawings, either individually or in combination.

The present invention relates to a semiconductor device and a method for fabricating the semiconductor device. The device comprises a semiconductor layer and a stressor layer stacked on a substrate and confined to a cavity defined by an insulator barrier formed on the substrate. Confinement of the stressor layer to the cavity prevents cracking of the stressor layer, and thus fabrication of the stressor layer of desired thickness, which induces a desired strain on the semiconductor layer. Thereby, the present invention allows achieving desired radiation absorption or emission characteristics without a need for changing conditions of fabricating the semiconductor device, and thus reducing a cost and complexity of the fabrication process, while minimizing damages during fabrication.

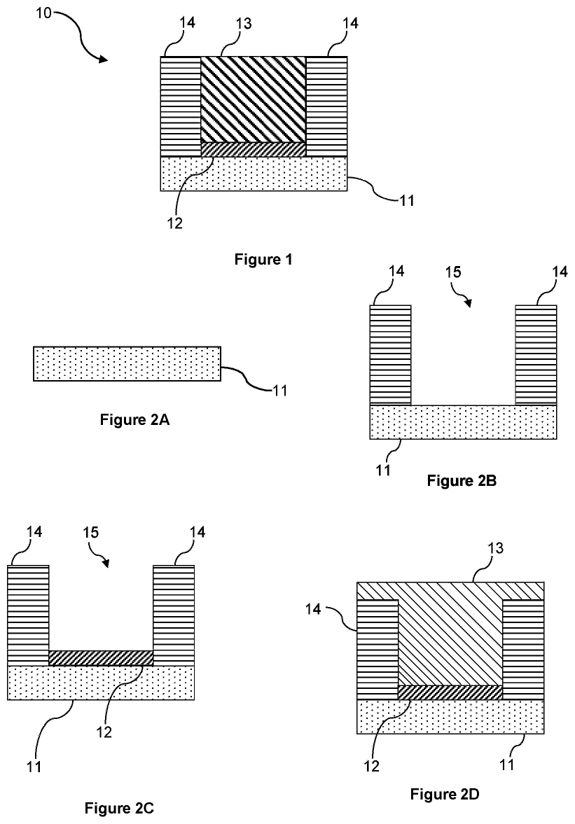

Referring to the accompanying drawings, FIG. 1 shows a cross sectional view of a semiconductor device (10), in accordance with an exemplary embodiment of the present invention. The device (10) comprises a substrate (11), a semiconductor layer (12), a stressor layer (13), an insulator barrier (14) and a plurality of electrical connectors (not shown). Preferably, the substrate (11) is a silicon-on-insulator (SOI) substrate formed as a flat support layer, as shown in FIG. 2A, for supporting components formed thereon. Alternatively, the substrate may also be a silicon substrate, wherein additional layers of semiconductor or insulator material may be formed on the silicon substrate before forming the semiconductor layer (12). The semiconductor layer (12) is epitaxially grown on top of the substrate (11) and is capable of absorbing or emitting an electromagnetic radiation such as near infrared radiation and visible light radiation. In a preferred embodiment, the device (10) is a germanium (Ge) photodiode and the semiconductor layer (12) is a Ge layer epitaxially grown on the substrate (11) by a chemical vapor deposition (CVD) process such as ultra-high vacuum CVD (UI-IVCVD), reduced pressure CVD (RPCVD) and atmospheric-pressure CVD (APCVD). Alternatively, the device (10) may be a light emitting diode (LED), laser diode, photovoltaic cell, sensor and neutron detector, and the semiconductor layer (12) may be a layer of silicon (Si), SiGe, silicon carbide (SiC), gallium arsenide (GaAs), aluminum GaAs (AlGaAs), gallium nitride (GaN), aluminum GaN (AlGaN), indium phosphide (InP), indium GaAs phosphide (InGaAsP) or a combination of two or more semiconductors. Similarly, the semiconductor layer (12) may be grown on the substrate (11) by means of a molecular beam epitaxy (MBE) process.

The stressor layer (13) is on top of the semiconductor layer (12) such that the semiconductor layer (12) is sandwiched between the stressor layer (13) and the substrate (11). The stressor layer (13) induces strain on the semiconductor layer (12), wherein the amount of induced strain is directly proportion to thickness of the stressor layer (13). Preferably, the thickness of the stressor layer (13) is within a range of 10-1500 nanometers (nm). In case of multiple stressor layers, the amount of induced strain is directly proportion to combined thickness of the stressor layers. Preferably, the stressor layer (13) is a single layer of complementary metal oxide semiconductor (CMOS) process-compatible dielectric, more preferably silicon nitride (SiN) layer. Alternatively, the stressor layer (13) is made of any other conventional CMOS process-compatible dielectric such as silicon dioxide, silicon oxynitride and boron. The stressor layer (13) is formed by chemical vapor deposition (CVD) such as plasma enhanced CVD (PECVD) and low pressure CVD (LPCVD), of the CMOS process-compatible dielectric. However, the stressor layer (13) may also be formed of by means of a sputtering process like reactive radio frequency (RF) magnetron sputtering process.

The insulator barrier (14) provided on the substrate (11) defines a cavity (15), as shown in FIG. 2B. The barrier (14) forms a perimeter around the cavity (15) while the substrate (11) forms a bottom of the cavity (15), such that the semiconductor layer (12) and the stressor layer (13) are confined to the cavity (15), as shown in FIG. 2D. Preferably, the barrier (14) is formed of silicon dioxide (SiO₂). Alternatively, any other conventional insulator material can be used for forming the barrier (14). Preferably, the barrier (14) may be ring-shaped. Alternatively, the barrier (14) can also be of polygonal shape, oval shape or any other shape capable of defining the cavity (15). Similarly, a cross section of the cavity (15) may be polygonal shaped or curved. A maximum width of the stressor layer (13) and the semiconductor layer (12) do not exceed that of the cavity (15). Furthermore, the stressor layer (13) is configured in such a way that a combined thickness of the semiconductor layer (12) and the stressor layer (13) does not exceed depth of the cavity (15), as shown in FIG. 1.

Confinement of the stressor layer (13) to the cavity (15) prevents cracking which is often seen when the thickness of the stressor layer exceeds a few hundred nanometers (nm), in particular 200 nm. Thus, the present invention allows increasing the thickness of the stressor layer (13) beyond 200 nm without cracking by increasing the depth of the cavity (15), which in turn increases the strain induced on the semiconductor layer (12). Furthermore, the increased strain enhances absorption or emission capability of the semiconductor layer (12). By this way, the present invention allows achieving desired radiation absorption or emission characteristics without a need for changing conditions of fabricating the semiconductor device, and thus a semiconductor device with desired characteristics can be fabricated in a simple and inexpensive manner, while minimizing damages during fabrication.

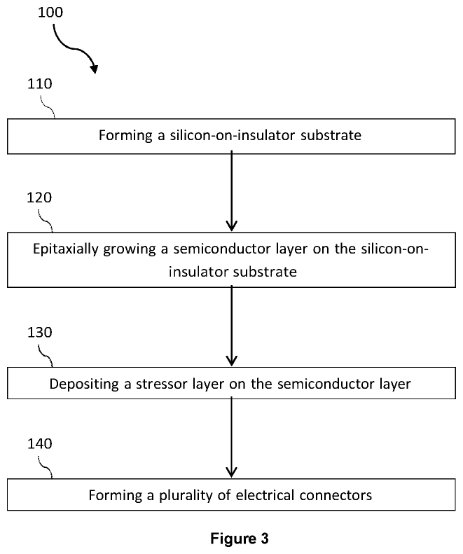

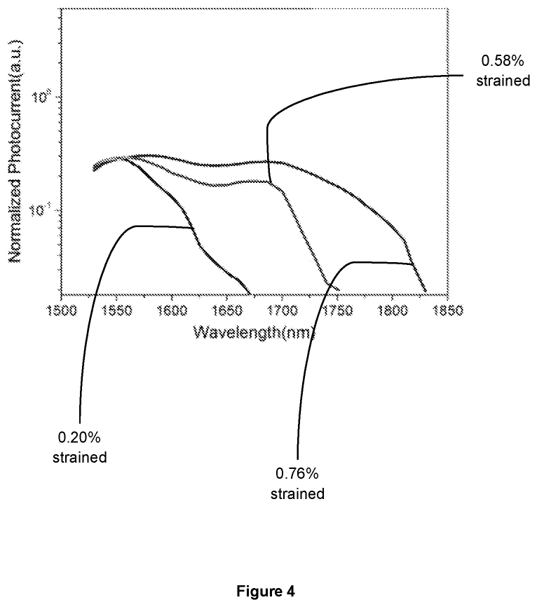

FIG. 3 shows a flow diagram of a method for fabricating a stressor layer for a semiconductor device, in accordance with an exemplary embodiment of the present invention. The method (100) comprises the steps of: (a) forming a substrate (110), epitaxially growing a semiconductor layer on the substrate (120), depositing a stressor layer on the semiconductor layer (130) and forming a plurality of electrical connectors (140). Preferably, the semiconductor device is germanium (Ge) photodiode and the substrate is a silicon-on-insulator (SOI) substrate, wherein a portion of a top surface of the substrate is heavily doped with impurities while forming the substrate. Similarly, a portion of a top surface of the semiconductor layer is heavily doped with impurities of opposite type. Preferably, doping density in these heavily doped portions is about 10²⁰ atoms per cubic centimeter. Alternatively, the doping density may be varied according to the materials used for forming the substrate and the semiconductor layer. However, if the substrate is doped with p-type impurities, the semiconductor layer is doped with n-type impurities and vice versa. Furthermore, the semiconductor device may also be a semiconductor diode, laser diode, light emitting diode, photovoltaic cell, sensor or neutron detector, and the substrate may be a silicon substrate formed with doped regions.

In a preferred embodiment, he semiconductor layer is a Ge layer capable of absorbing near infrared radiation. Alternatively, the semiconductor layer may be a layer of silicon (Si), SiGe, silicon carbide (SiC), gallium arsenide (GaAs), aluminum GaAs (AlGaAs), gallium nitride (GaN), aluminum GaN (AlGaN), indium phosphide (InP), indium GaAs phosphide (InGaAsP) or a combination of two or more semiconductors, capable of emitting or absorbing an electromagnetic radiation such as visible light radiation.

Preferably, the stressor layer is deposited by means of chemical vapor deposition (CVD) such as plasma enhanced CVD (PECVD) and low pressure CVD (LPCVD). Furthermore, the stressor layer is formed by depositing a complementary metal oxide semiconductor (CMOS) dielectric, preferably Si nitride (SiN), on the SOI substrate by CVD process. The stressor layer is capable of inducing strain on the semiconductor layer, wherein the strain influences a radiation absorption or emitting capability of the semiconductor layer. For example, if the semiconductor layer is a Ge layer, then the induced strain may reduce a direct bandgap of the germanium from the bulk value of 0.80 electronvolt (eV), which in turn enhances absorption at longer wavelengths into the L-band.

In a preferred embodiment, during epitaxially growing the semiconductor layer, an insulator barrier is formed on the substrate to define a cavity wherein the barrier forms a perimeter of the cavity and the substrate forms a bottom of the cavity, such that the semiconductor layer and the stressor layer are confined to the cavity. The barrier may be formed as a ring-, polygonal- or elliptical shaped and a cross section of the cavity may be formed as a box-shaped, curved or V-shaped.

Furthermore, excess stressor layer is removed, such that a combined thickness of the semiconductor layer and the stressor layer does not exceed a depth of the cavity, as shown in FIG. 1. Preferably, the excess stressor layer is removed by chemical mechanical polishing (CMP). More preferably, a CMP slurry with high Si₃N₄:SiO₂ selectivity is used to remove the excess stressor layer, such that a top portion of the stressor layer and a top portion of the insulator barrier form a single flat surface. Additionally, the electrical connectors are formed for electrically connecting the semiconductor device to an external circuit, more particularly for connecting the semiconductor layer and the substrate to the external circuit. The external circuit may be any conventional power source, controlling devices, photonic devices and the like. The electrical connectors are connected to the semiconductor layer and the substrate by forming holes through the stressor layer or the insulator barrier and inserting a conductive material through the holes to make electrical contact with the semiconductor layer and the substrate. Furthermore, the connectors may include bond pads positioned on top or side surface of the semiconductor device.

The insulator barrier functions to confine the semiconductor layer within the cavity while growing the semiconductor layer on the substrate and to confine the stressor layer to the cavity while depositing the stressor layer on top of the semiconductor layer, such that a maximum width of the stressor layer and the semiconductor layer do not exceed a maximum width of the cavity. Furthermore, a combined thickness of the semiconductor layer and the stressor layer does not exceed a depth of the cavity.

Confinement of the stressor layer to the cavity prevents cracking which is often seen when thickness of the stressor layer exceeds a few hundred nanometers, especially when exceeds 200 nm. Thus, thickness of the stressor layer can be increased without cracking by increasing a depth of the cavity, which in turn increases the strain induced on the semiconductor layer without damaging the stressor layer. Furthermore, the increased strain enhances absorption or emission capability of the semiconductor layer. By this way, the present invention allows manufacture of semiconductor device with desired radiation absorption or emission characteristics in a simple and inexpensive manner without a need for changing conditions of fabricating the semiconductor device, while minimizing damages during fabrication.

Even though the above embodiments show the present invention being implemented for inducing strain on a semiconductor layer to modify its radiation absorption or emitting properties, it is to be understood that the present invention may also be applied for modifying any other semiconductor properties that can be modified when the bandgap of the semiconductor layer is reduced by externally inducing strain. It includes but not limited to electron mobility, laser states, transistor switching speeds and photon absorption.

The terminology used herein is for the purpose of describing particular example embodiments only and is not intended to be limiting. As used herein, the singular forms “a”, “an” and “the” may be intended to include the plural forms as well, unless the context clearly indicates otherwise. The terms “comprises”, “comprising”, “including” and “having” are inclusive and therefore specify the presence of stated features, integers, steps, operations, elements and/or components, but do not preclude the presence or addition of one or more other features, integers, steps, operations, elements, components and/or groups thereof.

The method steps, processes and operations described herein are not to be construed as necessarily requiring their performance in the particular order discussed or illustrated, unless specifically identified as an order of performance. It is also to be understood that additional or alternative steps may be employed. The use of the expression “at least” or at “least one” suggests the use of one or more elements, as the use may be in one of the embodiments to achieve one or more of the desired objects or results.

1. A semiconductor device (10), comprising:
(a) a substrate (11);
(b) at least one stressor layer (13); and
(c) at least one semiconductor layer (12) sandwiched between said substrate (11) and said stressor layer (13),
characterized in that an insulator barrier (14) provided on said substrate (11) defines a cavity (15), such that said semiconductor layer (12) and said stressor layer (13) are confined to said cavity.

2. The semiconductor device (10) of claim 1, wherein said barrier (14) forms a perimeter around said cavity (15) and said substrate (11) forms a bottom of said cavity (15).

3. The semiconductor device (10) of claim 1, wherein a plurality of electrical connectors electrically connects said semiconductor device (10) to an external circuit.

4. The semiconductor device (10) of claim 1, wherein said semiconductor layer (12) is capable of absorbing an electromagnetic radiation.

5. The semiconductor device (10) of claim 1, wherein said semiconductor layer (12) is capable of emitting an electromagnetic radiation.

6. The semiconductor device (10) of claim 1, wherein said stressor layer (13) is formed by chemical vapor deposition of a complementary metal oxide semiconductor process-compatible dielectric.

7. The semiconductor device (10) of claim 6, wherein said complementary metal oxide semiconductor process-compatible dielectric is silicon nitride.

8. The semiconductor device (10) of claim 1, wherein thickness of said stressor layer (13) is within a range of 10-1500 nanometers.

9. The semiconductor device (10) of claim 1, wherein said semiconductor device (10) is at least one of a light emitting diode, a laser diode and a photodiode.

10. A method (100) for fabricating a semiconductor device, comprising the steps of:
(a) forming a substrate (110);
(b) epitaxially growing at least one semiconductor layer on said substrate (120);
(c) depositing at least one stressor layer on said semiconductor layer (130), characterized in that epitaxially growing said semiconductor layer includes forming an insulator barrier on said substrate to define a cavity, such that said semiconductor layer and said stressor layer are confined to said cavity.

11. The method (100) of claim 9, wherein said barrier forms a perimeter around said cavity while said substrate forms a bottom of said cavity.

12. The method (100) of claim 9, further comprising the step of forming a plurality of electrical connectors (140), wherein the connectors are capable of electrically connecting said semiconductor device to an external circuit.

13. The method (100) of claim 9, wherein said step of depositing includes depositing a complementary metal oxide semiconductor process-compatible dielectric on said semiconductor layer by means of chemical vapor deposition.

14. The method (100) of claim 9, further comprising the step of removing excess stressor layer, such that a combined thickness of said semiconductor layer and said stressor layer does not exceed a depth of said cavity.

15. The method (100) of claim 9, wherein said step of removing excess stressor layer includes chemical mechanical polishing process and/or chemical etching process.

16. The method (100) of claim 9, wherein thickness of said stressor layer is within a range of 10-1500 nanometers.
